(19) United States
(12) Patent Application Publication
(10) Pub. No.: US 2016/0247961 A1
(43) Pub. Date: Aug. 25, 2016

(54) METHOD FOR DESIGNING AND FABRICATING A DEVICE THAT FORCES ATOMS TO EMIT SPECTRUMS

(71) Applicant: Sun-Ho JUNG, Gyeonggi-do (KR)

(72) Inventor: SUN-HO JUNG, YONGIN-SI, GYEONGGI-DO (KR)

(21) Appl. No.: 15/025,885

(22) PCT Filed: Oct. 15, 2014
(86) PCT No.: PCT/KR2014/009651

§ 371 Date: Mar. 29, 2016

(30) Foreign Application Priority Data
Oct. 28, 2013 (KR) 10-2013-0128298

(51) Int. Cl. H01L 33/00

(52) U.S. Cl. CPC H01L 33/005

(57) ABSTRACT

A method for designing and fabricating a device that forces atoms to emit spectrums. The method utilizes a proton-electron pair theory and the shell orbit velocity-radius product law based on Rydberg formula which has been confirmed experimentally with Hydrogen Gas Lamp refuting not only Bohr's photon emission hypothesis but also band gap theory. The method improves not only the performance and quality of LED but also reduces heat loss as well as production costs thereof.

### RELATED APPLICATIONS

This application is §371 application from PCT/KR2014/009651 filed Oct. 15, 2014, which claims priority from Korean Patent Application No. 10-2013-0128298 filed Oct. 28, 2013, each of which is incorporated herein by reference in its entirety.

### BACKGROUND OF THE INVENTION

1. Field of the Invention

The present invention relates to a method of designing and fabricating a device that supplies ionizing energy to orbiting electrons in the outermost proton-electron pairs of atoms implanted in a semiconductor substrate.

2. Description of the Prior Art

The band gap theory that explains prior art of LED (Light Emitting Diode) design and fabrication is explained as follows. When a DC voltage is applied to an anode, electrons in the n-type semiconductor flow across p-n junction towards the anode stimulating electrons in the valence band of the semiconductor to jump to conduction band. The energy level difference between conduction band and valence band of the semiconductor is explained to be the source of the spectrums radiated from the LED.

However, in the case of a hydrogen atom, the mass of the proton weighs as much as 1,836 times that of the electron, and the gravity acting between the proton and the electron is only 4.418×10⁻⁴⁰ of the Coulomb force acting between them. Therefore, it is not possible for a stimulated electron to jump by itself from valence band to conduction band because of the Coulomb force that holds onto its pair orbiting electron.

### SUMMARY OF THE INVENTION

The present invention was motivated by the absurdity of band gap theory which seems to have its root in the mistaken photon emission hypothesis proposed by Bohr in 1913.

(1) Bohr overlooked the fact that a Hydrogen Gas Lamp is excited by 5,000V anode voltage implies that hydrogen atoms in the vacuum tube of the Gas Lamp are all ionized when they are excited to radiate spectrums;

(2) Bohr was unaware of the fact that the every electric flux of orbiting electron (e⁰) in a hydrogen atom is held by electric flux from its pair proton (P⁰) completely, and thus it is not free to emit a spectrum unless it is ionized;

(3) Bohr was unaware of the fact that the spectrum emitted by an electron (e⁰) is its kinetic energy when it is ionized and freed from its pair proton to become a free electron ion (e⁻);

(4) Bohr was unaware of the fact that when the orbiting electron (e⁰) is ionized and leaves its shell orbit, it becomes a free electron ion (e⁻) that cannot orbit at a larger distance away from its shell orbit;

(5) Bohr was unaware of the fact that his hypothesis of quantized orbit established outside the shell orbit of a hydrogen atom, that is nothing but a proton-electron pair (P⁰e⁰), is purely imaginary and cannot exist in reality;

(6) Bohr fails to explain any force that would enable an orbiting electron to jump from one orbit to another;

(7) Bohr was unaware of the fact that the orbiting electron of a proton-electron pair ionizes and radiates its kinetic energy only when the orbiting electron receives enough energy from other sources to free itself from its pair proton.

In the present invention, corrections to above-described Bohr's mistakes are made, first by applying Gauss's law to the Rutherford atomic model to discover proton-electron pair theory that describes protons and electrons in an atom form proton-electron pairs (P⁰e⁰) using all of their electric flux lines.

Using the proton-electron pair theory, the meanings of the integers j and n in the Rydberg formula {κ=R_{H}(1/n²−1/j²)} that accurately calculates the wavelength of a hydrogen spectrum are explained as follows.

(1) Because several thousand volts of DC voltage applied to the Anode of Hydrogen Gas Lamp ionizes every hydrogen atom which is a proton-electron pair (P⁰e⁰) producing a proton ion (P⁺) and an electron ion (e⁻), the emission of spectrums from hydrogen atoms are essentially acts of proton ions (P⁺) and the electron ions (e⁻).

(2) The integer j in the Rydberg formula means that the proton ion (P⁺) captures the electron ion (e⁻) to form a proton-electron pair (P⁰←e⁰), when the velocity-distance product (vⱼrⱼ) of an electron ion (e⁻), where vⱼ denotes the velocity of electron ion (e⁻) and rⱼ denotes its distance from the proton ion (P⁺) is j times the shell orbit velocity-radius product (v₁r₁) where r₁ denotes the radius of the shell orbit and v₁ denotes the velocity of the electron ion (e⁻), that is, vⱼrⱼ=jv₁r₁. (Because the proton ion (P⁺) captures the electron ion (e⁻) using all their electric flux lines, they become a proton (P⁰) and an electron (e⁰) while the proton pulls electron to the shell orbit. For this reason, the proton and the electron do not form a complete proton-electron pair (P⁰e⁰) and are in a state in which the proton (P⁰) captures and pulls the electron (e⁰). To express this state, an arrow is added as (P⁰←e⁰)).

(3) The integer n in the Rydberg formula means that the proton (P⁰) in the proton-electron pair (P⁰←e⁰) is ionized again while the proton (P⁰) in the proton-electron pair (P⁰←e⁰) pulls the electron (e⁰) to the shell orbit, when the velocity-distance product (vₙrₙ) is n times the shell orbit velocity-radius product (v₁r₁), that is, vₙrₙ=nv₁r₁.

(4) The electron ion (e⁻) receives kinetic energy [W_{(j,n)}=mv₁²(1/n²−1/j²)] from its pair proton while it is pulled from the distance (rⱼ) at which it is captured by the proton ion (P⁺) to the distance (rₙ) at which it is ionized again, and the energy of the spectrum emitted from ionized electron (e⁻) is equal to the kinetic energy of the electron it received from its pair proton.

Using such results, the wavelengths of spectra and frequencies thereof emitted from hydrogen atom can be calculated, and the results of the calculation are shown below.

λ and ν when captured electron is ionized by 13.6 eV at position n=1 (0.05 nm shell orbit)

| | n | j | 1/nn − 1/jj | W_{(j, n)} | [symbol] | κ | λ | ν |
|---|---|---|---|---|---|---|---|---|
| Lyman(1, 6) | 1 | 6 | 0.9722 | 4.237E−18 | 1.066E+07 | 1.066E+07 | 93.78 | 3.199E+15 |
| Lyman(1, 5) | 1 | 5 | 0.9600 | 4.184E−18 | 1.053E+07 | 1.053E+07 | 94.98 | 3.159E+15 |
| Lyman(1, 4) | 1 | 4 | 0.9375 | 4.085E−18 | 1.028E+07 | 1.028E+07 | 97.25 | 3.085E+15 |
| Lyman(1, 3) | 1 | 3 | 0.8889 | 3.874E−18 | 9.749E+06 | 9.749E+06 | 102.57 | 2.925E+15 |
| Lyman(1, 2) | 1 | 2 | 0.7500 | 3.268E−18 | 8.226E+06 | 8.226E+06 | 121.57 | 2.468E+15 |

[symbol]

indicates data missing or illegible when filed

λ and ν when captured electron is ionized by 3.499 eV at position n=2 (0.206 nm from proton)

| | n | j | 1/nn − 1/jj | W_{(j, n)} | [symbol] | κ | λ | ν |
|---|---|---|---|---|---|---|---|---|
| Balmer(2, 7) | 2 | 7 | 0.2296 | 1.002E−18 | 2.518E+06 | 2.518E+06 | 397.12 | 7.554E+14 |
| Balmer(2, 6) | 2 | 6 | 0.2222 | 9.684E−19 | 2.437E+06 | 2.437E+06 | 410.29 | 7.312E+14 |
| Balmer(2, 5) | 2 | 5 | 0.2100 | 9.152E−19 | 2.303E+06 | 2.303E+06 | 434.17 | 6.910E+14 |
| Balmer(2, 4) | 2 | 4 | 0.1875 | 8.171E−19 | 2.056E+06 | 2.056E+06 | 486.27 | 6.169E+14 |
| Balmer(2, 3) | 2 | 3 | 0.1389 | 6.053E−19 | 1.523E+06 | 1.523E+06 | 656.47 | 4.570E+14 |

[symbol]

indicates data missing or illegible when filed

λ and ν when captured electron is ionized by 1.555 eV at position n=3 (0.463 nm from proton)

| | n | j | 1/nn − 1/jj | W_{(j, n)} | [symbol] | κ | λ | ν |
|---|---|---|---|---|---|---|---|---|
| Paschen(3, 8) | 3 | 8 | 0.0955 | 4.161E−19 | 1.047E+06 | 1.047E+06 | 954.86 | 3.142E+14 |
| Paschen(3, 7) | 3 | 7 | 0.0907 | 3.953E−19 | 9.948E+05 | 9.948E+05 | 1005.22 | 2.984E+14 |
| Paschen(3, 6) | 3 | 6 | 0.0833 | 3.632E−19 | 9.140E+05 | 9.140E+05 | 1094.12 | 2.742E+14 |
| Paschen(3, 5) | 3 | 5 | 0.0711 | 3.099E−19 | 7.799E+05 | 7.799E+05 | 1282.17 | 2.340E+14 |
| Paschen(3, 4) | 3 | 4 | 0.0486 | 2.118E−19 | 5.331E+05 | 5.332E+05 | 1875.63 | 1.599E+14 |

[symbol]

indicates data missing or illegible when filed

λ and ν when captured electron is ionized by 0.875 eV at position n=4 (0.823 nm from proton)

| | n | j | 1/nn − 1/jj | W_{(j, n)} | [symbol] | κ | λ | ν |
|---|---|---|---|---|---|---|---|---|
| Brackett(4, 9) | 4 | 9 | 0.0502 | 2.186E−19 | 5.501E+05 | 5.501E+05 | 1817.92 | 1.650E+14 |
| Brackett(4, 8) | 4 | 8 | 0.0469 | 2.043E−19 | 5.141E+05 | 5.141E+05 | 1945.10 | 1.542E+14 |
| Brackett(4, 7) | 4 | 7 | 0.0421 | 1.834E−19 | 4.616E+05 | 4.617E+05 | 2166.13 | 1.385E+14 |
| Brackett(4, 6) | 4 | 6 | 0.0347 | 1.513E−19 | 3.808E+05 | 3.808E+05 | 2625.88 | 1.142E+14 |
| Brackett(4, 5) | 4 | 5 | 0.0225 | 9.805E−20 | 2.468E+05 | 2.468E+05 | 4052.28 | 7.403E+13 |

[symbol]

indicates data missing or illegible when filed

λ and ν when captured electron is ionized by 0.56 eV at position n=5 (1.286 nm from proton)

| | n | j | 1/nn − 1/jj | W_{(j, n)} | [symbol] | κ | λ | ν |
|---|---|---|---|---|---|---|---|---|
| Pfund(5, 10) | 5 | 10 | 0.0300 | 1.307E−19 | 3.290E+05 | 3.290E+05 | 3039.21 | 9.871E+13 |
| Pfund(5, 9) | 5 | 9 | 0.0277 | 1.205E−19 | 3.033E+05 | 3.033E+05 | 3297.00 | 9.099E+13 |
| Pfund(5, 8) | 5 | 8 | 0.0244 | 1.062E−19 | 2.673E+05 | 2.673E+05 | 3740.57 | 8.020E+13 |
| Pfund(5, 7) | 5 | 7 | 0.0196 | 8.538E−20 | 2.149E+05 | 2.149E+05 | 4653.79 | 6.446E+13 |
| Pfund(5, 6) | 5 | 6 | 0.0122 | 5.326E−20 | 1.340E+05 | 1.341E+05 | 7459.88 | 4.022E+13 |

[symbol]

indicates data missing or illegible when filed

λ and ν when captured electron is ionized by 0.389 eV at position n=6 (1.852 nm from proton)

| | n | j | 1/nn − 1/jj | W_{(j, n)} | [symbol] | κ | λ | ν |
|---|---|---|---|---|---|---|---|---|
| Humphrey(6, 11) | 6 | 11 | 0.0195 | 8.504E−20 | 2.140E+05 | 2.140E+05 | 4672.52 | 6.421E+13 |
| Humphrey(6, 10) | 6 | 10 | 0.0178 | 7.747E−20 | 1.950E+05 | 1.950E+05 | 5128.67 | 5.849E+13 |
| Humphrey(6, 9) | 6 | 9 | 0.0154 | 6.725E−20 | 1.693E+05 | 1.693E+05 | 5908.23 | 5.078E+13 |
| Humphrey(6, 8) | 6 | 8 | 0.0122 | 5.296E−20 | 1.333E+05 | 1.333E+05 | 7502.51 | 3.999E+13 |
| Humphrey(6, 7) | 6 | 7 | 0.0074 | 3.212E−20 | 8.083E+04 | 8.083E+04 | 12371.93 | 2.425E+13 |

[symbol]

indicates data missing or illegible when filed

The Tables above calculated with the proton-electron pair theory and the shell orbit velocity-radius product law are identical to those measured by physicists experimentally. Thus, the Tables prove the truth of the proton-electron pair theory and the shell orbit velocity-distance product law.

Therefore, the object of the present invention is to provide correct means to apply Rydberg formula to outermost proton-electron pairs of spectrum radiating atoms in such a way that the way hydrogen spectrums are generated can be correctly replicated by other spectrum emitting atoms and force them to radiate desired spectrums providing means to improve the performance and quality of the spectrum emitting device and reduce the fabrication cost.

### BRIEF DESCRIPTION OF THE DRAWINGS

FIG. 1 is a flow chart showing a process for designing a spectral emitting device according to an embodiment of the present invention.

FIG. 2 is a schematic diagram showing the structure of an ultraviolet light-emitting device according to an embodiment of the present invention.

FIG. 3 is a schematic diagram illustrating the functions of four semiconductor layers that are disposed between an Anode and a Cathode.

### DETAILED DESCRIPTION OF THE INVENTION

According to a first characteristic of the present invention, a method for designing and fabricating a device for emitting spectrums is dramatically improved by applying a new finding [that because protons and electrons in a hydrogen atom form proton-electron pairs using all the electric flux lines thereof even when the number of protons and electrons in the atom is large, the fact that ionization energy (qVᵢₒₙ) applied to the atom ionizes a proton-electron pair (P⁰e⁰) in the outermost proton-electron pair of the atom to produce a proton ion (P⁺) and an electron ion (e⁻) is applied to analyze the meanings of the two integers n and j in the Rydberg formula

$$κ = {R}_{H} ( 1 / {n}^{2} - 1 / {j}^{2} )$$

$$( κ = 1 / λ = {R}_{H} ( 1 / {n}^{2} - 1 / {j}^{2} ) n = 2 , j = 3 , 4 , 5 , , , )$$

that accurately predicts the wavelength of a spectrum emitted from a hydrogen atom, and as a result, a spectrum is emitted because the proton keeps the shell orbit velocity-distance product law to other atom.

According to a second characteristic of the present invention, there is provided a method of calculating the velocity (v₁) and the radius (r₁) of the orbiting electron in the outermost proton-electron pair (P⁰e⁰) of an atom and, by using new findings [that the velocity (v₁) of the electron (e⁰) in the shell orbit of the outermost proton-electron pair (P⁰e⁰) of the atom, is calculated from the equation ( ), and the radius (r₁) of the shell orbit is calculated from the equation ( ).

According to a third characteristic of the present invention, there is used a new finding [according to the shell orbit velocity-radius product law, a proton ion (P⁺) produced from a proton-electron pair when it is ionized captures only an electron ion (e⁻) when its velocity-distance product (vr) is integer multiples of shell orbit velocity-distance product (v₁r₁).

According to a fourth characteristic of the present invention, there is used a new finding [that when the proton ion (P⁺) captures the electron ion (e⁻) and pulls it to its shell orbit, it jumps positions corresponding to integer multiple of the shell orbit velocity-radius product (v₁r₁).

According to a fifth characteristic of the present invention, a new finding [that a plasma zone is produced in which the proton ion (P⁺) and the electron ion (e⁻), produced from ionized proton-electron pairs (P⁰e⁰) in the outermost proton-electron pairs of the atom, is present together with the proton-electron pair (P⁰←e⁰) that is in a process of pulling captured electron ion (e⁻) to its shell orbit is used in this method of designing and fabricating a device that forces atoms to emit spectrums.

According to a sixth characteristic of the present invention, a new finding [that the distribution of electrostatic field and the velocity of free moving electrons in the plasma zone influences the emission of desired spectrums from atoms] is used to optimize the distribution of an electrostatic field in the plasma zone to thereby increase the efficiency of the spectrum emitting device.

According to a seventh characteristic of the present invention, the distribution density of light-emitting atoms in the spectral emitting device is changed over a region ranging from the surface of contact with a Cathode to the surface of contact with an Anode in order to optimize the distribution of an electrostatic field in the plasma zone.

According to the eighth characteristic of the present invention, the present invention comprises, before the testing and production of an actual product, performing a simulated operation on the table top to reduce trial and error in a product development process.

The method for designing and fabricating the spectrum emitting devices according to the present invention is based on the new discovery of the principles of spectrums emission from Hydrogen Gas Lamp as has been experimentally verified. Thus, the method of the present invention not only rationalizes design process but also provides means to improve the performance and quality of the device so designed and produced.

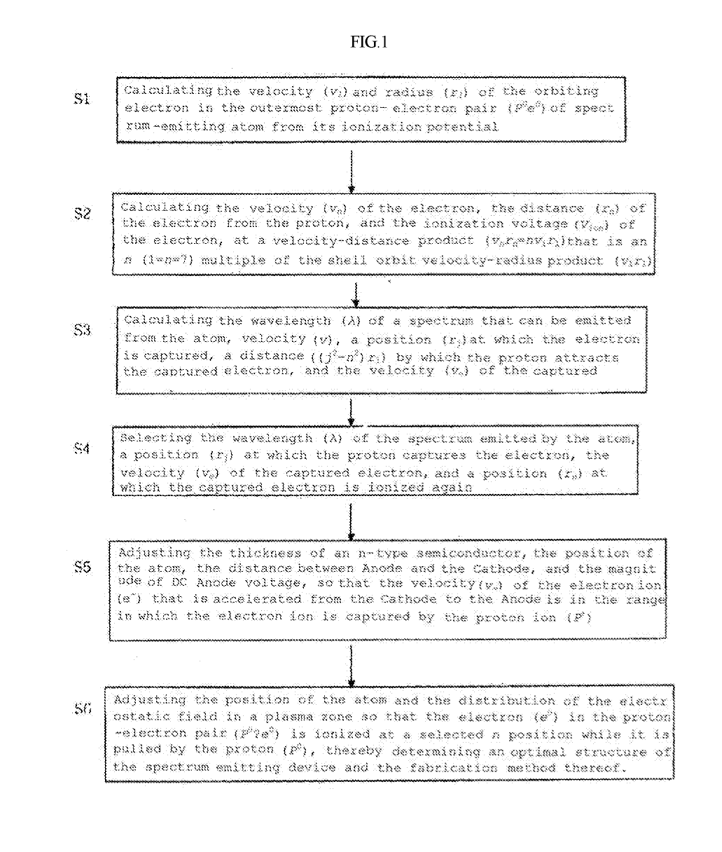

Hereinafter, an embodiment that realizes the above-described characteristics of the present invention will be described in detail with reference to FIG. 1.

First, a Ga atom is selected as an atom that emits a spectrum.

Then, based on the fact that the ionization voltage (Vᵢₒₙ) of the Ga atom is 5.999 volts, the velocity (v₁) of an electron in the outermost orbit of the Ga atom and the distance (r₁) from the electron to its pair proton are calculated using the equation (v₁=\sqrt{2qVᵢₒₙ/m}) and the equation (r₁=q/8πε₀Vᵢₒₙ) (S1).

Next, the velocity (vₙ) at a position corresponding to n (1≦n≦7) times the shell orbit velocity-distance product (v₁r₁), the distance (rₙ) from the electron to the proton, the velocity-distance product (vₙrn), and the ionization voltage (Vᵢₒₙ), are calculated as shown in the following Table (S2).

| n | v₁r₁ | vₙ | rₙ | Vᵢₒₙ |
|---|---|---|---|---|
| 1 | 1.740E−04 | 1.452E+06 | 1.199E−10 | 5.999 |
| 2 | 3.480E−04 | 7.258E+05 | 4.795E−10 | 1.500 |
| 3 | 5.220E−04 | 4.839E+05 | 1.079E−09 | 0.667 |
| 4 | 6.960E−04 | 3.629E+05 | 1.918E−09 | 0.375 |
| 5 | 8.700E−04 | 2.903E+05 | 2.997E−09 | 0.240 |
| 6 | 1.044E−03 | 2.419E+05 | 4.315E−09 | 0.167 |
| 7 | 1.218E−03 | 2.074E+05 | 5.873E−09 | 0.122 |

Regarding the results in the above Table, the proton-electron pair (P⁰e⁰) is separated into the proton ion (P⁺) and the electron ion (e⁻) by ionization, after which the proton ion (p⁺) captures the electron ion (e⁻) with the intention of making the original proton-electron pair (P⁰e⁰) recovered. The results in the above Table are those obtained by detecting the velocity-distance product (vr) that is the product of the velocity (v) and distance (r) of the electron ion (e⁻) that meets the proton ion (P⁺) with the intent to make the original proton-electron pair (P⁰e⁰), and applying the shell orbit velocity-radius product law according to which the proton ion (P⁺) captures the electron ion (e⁻) only if the velocity-distance product of the electron is an integer multiple of its shell orbit velocity-radius product (v₁r₁).

In the above Table, the velocity (vₙ) value of the electron at each position in the third column from the left of the Table is calculated using the equation vₙ=v₁/n, and the distance (rₙ) value of the electron in the fourth column from the left is calculated using the equation rₙ=n²r₁.

For example, if the n value, a position at which the proton ion (P⁺) captures the electron ion (e⁻), is 3, the velocity (v₃) of the electron ion (e⁻) is calculated using the equation v₃=v₁/3, and the distance (r₃) is calculated using the equation r₃=3²r₁. In other words, if the proton ion (P⁺) captured the electron ion (e⁻) at the position n=3, it means that the proton ion captured the electron ion when the velocity of the electron ion (e⁻) is ⅓ of the velocity (v₁) of the electron in the shell orbit and the distance of the electron is 9 times the radius (r₁) of the shell orbit.

Next, the following parameters are calculated as shown in Tables below (S3): the wavelength (λ) and frequency (ν) of a spectrum that can be emitted from the Ga atom; the position (rⱼ) at which the proton ion (P⁺) captures the electron ion (e⁻); the distance ((j²−n²) r₁) the proton in the proton-electron pair (P⁰←e⁰) pulled the electron; and the velocity of the captured electron ( [symbol] ) by the proton ion (P⁺).

λ, σ of spectrums radiated, captured position, pulled distance, and the velocity of captured electron, ionizing potential V=5.999 at n=1 (0.1199 nm from P⁰)

| n | j | 1/nn − 1/jj | W(j, n) | κ | λ | ν | rⱼ | (jj − nn)r₁ | [symbol] |
|---|---|---|---|---|---|---|---|---|---|
| 1 | 2 | 0.7500 | 1.440E−18 | 1.625E+06 | 275.9 | 1.088E+15 | 4.795E−10 | 3.597E−10 | 7.258E+05 |
| 1 | 3 | 0.8889 | 1.707E−18 | 4.296E+06 | 232.8 | 1.289E+15 | 1.079E−09 | 9.592E−10 | 4.839E+05 |
| 1 | 4 | 0.9375 | 1.801E−18 | 4.531E+06 | 220.7 | 1.359E+15 | 1.918E−09 | 1.799E−09 | 3.629E+05 |
| 1 | 5 | 0.9600 | 1.844E−18 | 4.640E+06 | 215.5 | 1.392E+15 | 2.997E−09 | 2.878E−09 | 2.903E+05 |
| 1 | 6 | 0.9722 | 1.867E−18 | 4.699E+06 | 212.8 | 1.410E+15 | 4.315E−09 | 4.197E−09 | 2.419E+05 |
| 1 | 7 | 0.9796 | 1.881E−18 | 4.735E+06 | 211.2 | 1.420E+15 | 5.873E−09 | 5.755E−09 | 2.074E+05 |

[symbol]

indicates data missing or illegible when filed

λ, ν of spectrums radiated, captured position, pulled distance, and the velocity of captured electron, ionizing potential V=1.5 at n=2 (0.4795 nm from P⁰)

| n | j | 1/nn − 1/jj | W(j, n) | κ | λ | ν | rⱼ | (jj − nn)r₁ | [symbol] |
|---|---|---|---|---|---|---|---|---|---|
| 2 | 3 | 0.1389 | 2.667E−19 | 6.713E+05 | 1,489.6 | 2.014E+14 | 1.079E−09 | 5.995E−10 | 4.839E+05 |
| 2 | 4 | 0.1875 | 3.601E−19 | 9.063E+05 | 1,103.4 | 2.719E+14 | 1.918E−09 | 1.439E−09 | 3.629E+05 |
| 2 | 5 | 0.2100 | 4.033E−19 | 1.015E+06 | 985.2 | 3.045E+14 | 2.997E−09 | 2.518E−09 | 2.903E+05 |
| 2 | 6 | 0.2222 | 4.268E−19 | 1.074E+06 | 931.0 | 3.222E+14 | 4.315E−09 | 3.837E−09 | 2.419E+05 |
| 2 | 7 | 0.2296 | 4.409E−19 | 1.110E+06 | 901.1 | 3.329E+14 | 5.873E−09 | 5.396E−09 | 2.074E+05 |

[symbol]

indicates data missing or illegible when filed

λ, ν of spectrums radiated, captured position, pulled distance, and the velocity of captured electron, ionizing potential V=0.667 at n=3 (1.079 nm from P⁰)

| n | j | 1/nn − 1/jj | W(j, n) | κ | λ | ν | rⱼ | (jj − nn)r₁ | [symbol] |
|---|---|---|---|---|---|---|---|---|---|
| 3 | 4 | 0.0486 | 9.336E−20 | 2.350E+05 | 4,256.0 | 7.049E+13 | 1.918E−09 | 8.393E−10 | 3.629E+05 |
| 3 | 5 | 0.0711 | 1.366E−19 | 3.437E+05 | 2,909.4 | 1.031E+14 | 2.997E−09 | 1.918E−09 | 2.903E+05 |
| 3 | 6 | 0.0833 | 1.600E−19 | 4.028E+05 | 2,482.7 | 1.208E+14 | 4.315E−09 | 3.237E−09 | 2.419E+05 |
| 3 | 7 | 0.0907 | 1.747E−19 | 4.384E+05 | 2,281.0 | 1.315E+14 | 5.873E−09 | 4.796E−09 | 2.074E+05 |

[symbol]

indicates data missing or illegible when filed

A, u of spectrums radiated, captured position, pulled distance, and the velocity of captured electron, ionizing potential V=0.375 at n=4 (1.918 nm from P⁰)

| n | j | 1/nn − 1/jj | W(j, n) | κ | λ | ν | rⱼ | (jj − nn)r₁ | [symbol] |
|---|---|---|---|---|---|---|---|---|---|
| 4 | 5 | 0.0225 | 4.321E−20 | 1.088E+05 | 9,195.1 | 3.263E+13 | 2.997E−09 | 1.079E−09 | 2.903E+05 |
| 4 | 6 | 0.0347 | 6.669E−20 | 1.678E+05 | 5,958.4 | 5.035E+13 | 4.315E−09 | 2.398E−09 | 2.419E+05 |
| 4 | 7 | 0.0421 | 8.084E−20 | 2.035E+05 | 4,915.2 | 6.104E+13 | 5.873E−09 | 3.957E−09 | 2.074E+05 |

[symbol]

indicates data missing or illegible when filed

For example, if it is assumed that a spectrum having a wavelength of 232.8 nm is selected from among various spectra that can be emitted from the Ga atom as shown in the above Tables, it reads that the proton ion (P⁺) captures an electron ion (e⁻) having the velocity vₑ=4.839×10⁺⁵ m/sec at the j=3 position (distance: 1.079 nm) as shown in the above Tables and pulls the captured electron ion to the shell orbit (n=1) (S4). Then, the applied voltage (Vₐ), the thickness of the p-type semiconductor, and the position of the proton-electron pair (P⁰e⁰) that is ionized, are controlled so that the velocity (vₑ) of the electron ion (e⁻) that is emitted from the n-type semiconductor becomes vₑ=4.839×10⁺⁵ m/sec at the position r₃=1.079 nm in the proton ion (P⁺) as shown in the above Tables (S5).

In order for the proton ion (P⁺) to capture the electron ion having the velocity vₑ=4.839×10⁺⁵ m/sec at the j=3 position (distance: 1.079 nm) to form a proton-electron pair (P⁰←e⁰) and then pull the electron (e⁰) to the orbit (n=1) without being ionized, the distribution of an electrostatic field in the plasma zone is adjusted so that a voltage of 1.5 volts or higher will not be applied to the proton-electron pair (P⁰←e⁰) in the plasma zone, thereby determining a method for designing and fabricating a spectrum emitting device having an optimal structure (S6).

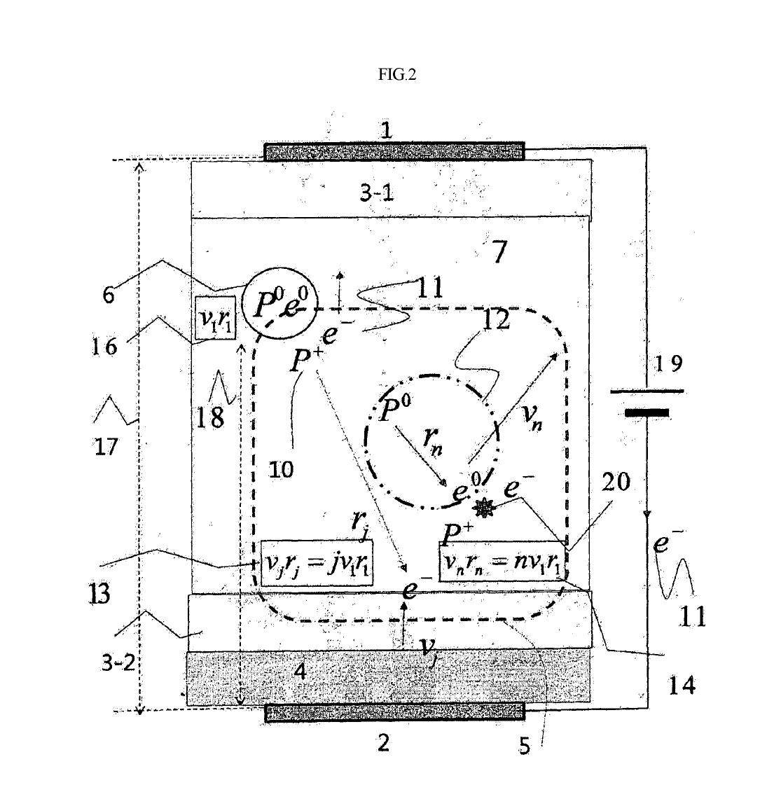

Referring to FIG. 2, a proton-electron pair (P⁰e⁰) 6 that emits a spectrum is ionized in a spectrum emitting device, and then a proton ion (P⁺) 10 is attracted towards Cathode 2, and an electron ion (e⁻) 11 emitted from an n-type semiconductor substrate 4 is accelerated to a velocity (vⱼ) by a voltage applied between the Anode 1 and the Cathode 2. When the electron ion (e⁻) 11 is at a distance of rⱼ from the proton ion (P⁺) 10, it is captured by the proton ion (P⁺) 10 to form a proton-electron pair (P⁰←e⁰) 12, and then the proton (P⁰) is ionized to emit a spectrum 20 while it pulls the electron to the n position.

Particularly, FIG. 2 illustrates that the proton ion (P⁺) 10 captures the electron ion (e⁻) 11 in the moment when the velocity-distance product (vⱼrⱼ) of the electron ion (e⁻) 11 becomes an integer (j) multiple of the shell orbit velocity-radius product (v₁r₁), that is, vⱼrⱼ=jv₁r₁ 13, and also illustrates that, at the n position at which the proton-electron pair (P⁰←e⁰) 12 is ionized again, the proton-electron pair is ionized in the moment when the velocity-distance product (vₙrₙ) of the electron becomes an integer (n) multiple of the shell orbit velocity-radius product (v₁r₁), that is, vₙrₙ=nv₁r₁ 14, and thus the electron (e⁰) captured by the proton (P⁰) is freed to become the electron ion (e⁻) 11, thereby emitting the spectrum 20. In addition, the dotted line in FIG. 2 indicates a zone in which plasma 5 is formed near the n-type semiconductor substrate 4.

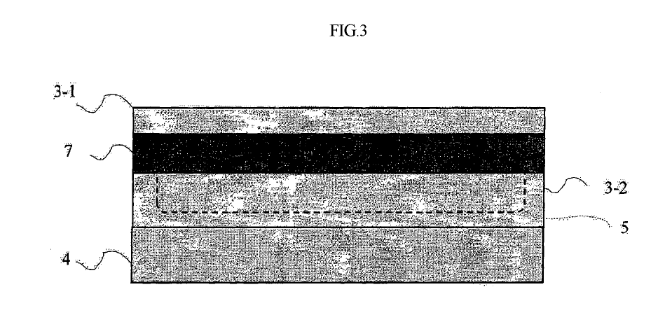

Referring to FIG. 3, a semiconductor substrate 7 including the proton-electron pair (P⁰e⁰) 6 that emits a spectrum is inserted between two silicon substrates 3-1 and 3-2 so that the distribution of an electrostatic field in the plasma zone 5 in which the proton ion (P⁺) 10 and the electron ion (e⁻) 11 are present together with the proton-electron pair 12 can be adjusted so that the light-emitting proton-electron pair (P⁰e⁰) 6 will be ionized while the proton-electron pair (P⁰←e⁰) 12 will be ionized again at a desired position (n).

Because the velocity of an electron ion motion that is emitted from an n-type semiconductor 4 becomes faster as it is far away from the Cathode, the thickness of the n-type semiconductor 4 is made thin so as to prevent a phenomenon in which the velocity of the electron ion (e⁻) becomes too fast by acceleration of a voltage 19 applied to the Anode so that the proton ion (P⁺) 10 cannot capture the electron ion (e⁻) 11.

In addition, in order to maintain the semiconductor substrate 7, on which proton-electron pairs (P⁰e⁰) in the valence band of the Ga atom are concentrated, at an appropriate distance from the n-type semiconductor 4, a silicon substrate 3-2 is inserted therebetween so as to reduce the density of the light-emitting proton-electron pairs (P⁰e⁰) 6 in the plasma zone 5 while adjusting the distribution of an electrostatic field in the plasma zone 5 so that the proton ion (P⁺) 10 will capture the electron ion (e⁻) 11 at a desired position, whereby the proton-electron pair (P⁰←e⁰) 12 will be ionized again at a desired position.

The present invention was motivated by the limits of the band gap theory originated from Bohr's photon emission hypothesis that overlooked the fact that 5,000V Anode potential at Hydrogen Gas Lamp ionizes hydrogen atoms. In the present invention, the phenomena of spectrum generation from Hydrogen Gas Lamp is closely replicated by first analyzing it in terms of the newly discovered Proton-Electron Pair Theory and the Shell Orbit Velocity Radius Product Law and by simulating the spectrum generating process of hydrogen atoms by the design and fabrication of a spectrum emitting device.

What makes it significant in the present invention is newly discovered proton-electron pair theory that makes it possible to apply the Rydberg formula [κ=R_{H}(1/n²−1/j²)] to the outermost proton-electron pair of spectrum emitting atoms because the formula provides means to calculate wavelengths and frequencies of spectrum emitted from spectrum emitting atoms taking full advantage of the meanings of the integers n and j in the formula. As a result, a source from which an electron acquires energy, a method by which an electron acquires energy to be ionized, and conditions in which an electron emits a spectrum, could be scientifically and accurately calculated. Thus, according to the present invention, a device that forces a spectrum to be emitted from any atom can be designed and fabricated.

Table below compares between the band gap theory and the shell orbit velocity-radius product law.

| | | Shell orbit velocity- |
|---|---|---|
| | Band gap theory | radius product law |
| Calculation of | Impossible | Possible |
| wavelength | | |
| Design specification | Cannot be provided | Provided |
| Number of spectra that | Very limited | Large |
| can be emitted | | |
| Quality control theory | Not present | Can be provided |
| Performance improvement | Not present | Can be provided |
| theory | | |
| Production cost control | Not present | Can be practiced |

From the Table above, it can be seen that the effect of the present invention that uses the shell orbit velocity-radius product law is far superior to that of the conventional art that vaguely explains spectrum emission from semiconductor material in terms of the band gap theory.

Specifically, the band gap theory simply states electron energy level differences between valence and conduction band in a spectrum emitting semiconductor providing no means to relate operating parameters of LEDs. Hence design and fabrication of spectrum emitting device is focused onto searching for semiconductor material that is possessed with particular band gap.

In comparison, according to the present invention that uses the shell orbit velocity-radius product law, conditions in which a spectrum is emitted is explained in terms of the behavior of electrons and protons involved in spectrum generation, thus providing means to control wavelengths and frequencies thereof that are emitted from an atom, and a method for designing and fabricating a device that forces any atom radiate particular wavelengths can be predicted by selecting a particular atom having specific ionization potential, and from the ionization potential of the atom chosen, spectrums having desired wavelengths can be selected from among a large number of spectra that can be emitted from the atom. Thus, the present invention provides not only guidelines for the development of a new product but also means to analyze production processes for improved quality, efficiency, performance improvement, and production costs reduction.

Thus, the present invention completely overcomes the limitations of conventional band gap theories and technologies of manufacturing spectrum emitting devices.

Particularly, in an example of the present invention, where an ultraviolet light-emitting diode having a wavelength of 250 nm or less was designed using only a Ga atom, a spectrum having a wavelength of 211.2-275.6 nm could be emitted from a single Ga atom using a very simple structure having only four semiconductor layers. This is a remarkable improvement compared conventional ultraviolet light-emitting diode because it was fabricated by precisely stacking as many as 17 semiconductor layers. This fully proves that the effect of the present invention is revolutionary.

1-6. (canceled)

7. A method for designing and fabricating a device that forces atoms to emit desired spectrums, comprising the steps of:
calculating a orbiting velocity v₁ of an electron in an outermost proton-electron pair P⁰e⁰ and a radius r₁ of a spectrum emitting atom from a first new finding that when an ionization energy qVᵢₒₙ is applied to the atom, the outermost proton-electron pair P⁰e⁰ of the atom ionizes producing a proton ion P⁺ and an electron ion e⁻, the orbiting velocity v₁ in the outermost proton-electron pair P⁰e⁰ is calculated from an equation v₁=\sqrt{2qVᵢₒₙ/m} and the radius r₁ of a shell orbit is calculated from the equation r₁=q/8πε₀ Vᵢₒₙ;
calculating the velocity vₙ of the electron from the equation vₙ=v₁/n, the distance rₙ from the electron to the proton from the equation rₙ=n²r₁, and an ionization potential Vᵢₒₙ from the equation mv₁²/2n² by use of a second new finding that the shell orbit velocity-radius product law according to which the proton ion P⁺ captures the electron ion e⁻ to form a proton-electron pair P⁰←e⁰ is when a velocity-distance product of the electron ion e⁻ becomes an integer j multiples of the shell orbit velocity-radius product v₁r₁ or vⱼrⱼ=jv₁r₁, and the proton P⁰ in the proton-electron pair P⁰←e⁰ is ionized again at a position corresponding to a velocity-distance product vₙrₙ=nv₁r₁₁ that is an integer n multiple of the shell orbit velocity-radius product v₁r₁ while it pulls the captured electron e⁰ to the shell orbit;
calculating a wavelength λ of a spectrum by use of a third finding that the wavelength λ of the spectrum emitted from the atom is determined using an equation
$$κ = \frac{1}{λ} = {GW}_{( j , n )} where G = \frac{{R}_{H}}{{mv}_{1}^{2}} = 2.51672139 \times {10}^{24} {m}^{- 1} {j}^{- 1}$$
and an equation
$${W}_{( n , j )} = {\int }_{{r}_{2}}^{{r}_{1}} \frac{{q}^{2}}{4 πɛ {mv}^{2}} d r = {mv}_{1}^{2} ( \frac{1}{{n}^{2}} - \frac{1}{{j}^{2}} ) ,$$
and calculating a frequency ν of the spectrum from the equation ν=c/λ with c=10⁸ m/sec, a position rⱼ, at which the proton ion P⁺ captured the electron ion e⁻, from an equation rⱼ=j² r₁, a distance the proton pulled the captured electron, from an equation (j²−n²)r₁, and a velocity vₑ of the electron, captured by the proton ion P⁺, from an equation vₑ=v₁/j;
determining a magnitude of an anode voltage, a thickness of a semiconductor substrate, and a position of the proton-electron pair of spectrum emitting atoms, so that a velocity of cathode electron ions, which are accelerated to an anode after the cathode electron ions are emitted from a cathode, reaches a velocity at which the orbiting electron of the outermost proton-electron pair of the spectrum emitting atoms get ionized; and
adjusting a position at which the outermost proton-electron pair P⁰←e⁰ is ionized, and a distribution of the electrostatic field in a plasma zone such that the orbiting electron e⁰ in the proton-electron pair P⁰←e⁰ being pulled by the proton to the shell orbit can be ionized at a selected position n, thereby determining an optimal structure of a spectrum emitting device and a fabrication method thereof.

8. The method of claim 7, wherein the semiconductor substrate comprises spectrum emitting proton-electron pairs of a mixture of various species of atoms to achieve a predetermined spectrum density distribution emitted from each of the atoms.

9. The method of claim 7, further comprising the step of switching the anode voltage to higher potentials such that the proton-electron pair P⁰←e⁰ that captured an electron ion at a j=7 position away from the proton ion P⁺ ionizes at a nearest n=6 position.

10. The method of claim 7, further comprising the step of utilizing two silicon substrates to increase the wavelength of spectrums emitted.

11. The method of claim 10, further comprising the step of adjusting the anode voltage, the position of the proton-electron pair and a resistivity of thee two silicon substrates so that the proton-electro pair P⁰←e⁰ is formed at a j>7 position away from the proton ion P⁺ and the electron e⁰ of the outermost proton-electron pair is ionized immediately after it collides with an electron emitted from the cathode.

12. The method of claim 7, further comprising the step of designing and fabricating the device with the ionization potential equal to a band gap energy of a light emitting semiconductor.

13. The method of claim 7, further comprising the step of changing a potential applied to the anode to change species of atoms ionized by the accelerated cathode electron ions colliding with them, thereby changing the wavelength of the spectrum emitted from the device.
